(19) United States
(12) Patent Application Publication
(10) Pub. No.: US 2004/0243891 A1
(43) Pub. Date: Dec. 2, 2004

(54) Failure analysis method of semiconductor device

(75) Inventor: Fumihito Ohta, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/717,506

(22) Filed: Nov. 21, 2003

(30) Foreign Application Priority Data
May 29, 2003 (JP) 2003-152178

(51) Int. Cl. G11C 29/00; G06F 11/00; G01R 31/30

(52) U.S. Cl. 714/721

(57) ABSTRACT

The number of failure bits is counted with respect to each row and each column in a fail bit map (9), to find respective average numbers of failure bits with respect to rows and columns. One-half of the average number of failure bits of rows is defined as a threshold value of rows, and one-half of the average number of failure bits of columns is defined as a threshold value of columns. Thereafter, on the basis of the respective threshold values of rows and columns, the number of failure bits is converted to digital form with respect to each row and each column. The respective average values of the digitized numbers of failure bits with respect to rows and columns are calculated, which are respectively referred to as average values of rows and columns. It is determined that a semiconductor device contains a block failure in a row direction, a block failure in a column direction, or a random block failure.

### BACKGROUND OF THE INVENTION

1. Field of the Invention

The present invention relates to a failure analysis method of a semiconductor device, which method more particularly relates to failure analysis of a block failure contained in a semiconductor device including a plurality of memory cells.

2. Description of the Background Art

A conventional method has been using an LSI tester for analyzing a failure of a semiconductor device including a plurality of memory cells arranged in a matrix. According to this failure analysis method using an LSI tester, all the memory cells in the semiconductor device are tested for electrical characteristic, and data of failure memory cells (hereinafter alternatively referred to as “failure bits”) are collected. The data thereby collected is displayed on a map in a matrix form (hereinafter alternatively referred to as a “fail bit map”), whereby the cause of failures is analyzed. The analysis of the cause of failures includes recognition of a pattern of a failure displayed on the fail bit map, and determination of the coincidence rate of this pattern with a specified pattern. According to the coincidence rate thereby obtained, the failure is classified as a block failure or a line failure.

An exemplary method of failure analysis using a fail bit map is introduced in Japanese Patent Application Laid-Open No. 2000-306395 (pp. 5-10 and FIGS. 1 through 14). According to the method of Japanese Patent Application Laid-Open No. 2000-306395, an LSI tester obtains fail bit data from a semiconductor device, which data thereafter undergoes physical conversion to be sorted in order of layout of the semiconductor device. On the basis of the fail bit data after physical conversion, it is judged whether each region defined in the semiconductor device has a large proportion of bit failures.

Classification in the conventional method of failure analysis is based on the coincidence rate of a failure pattern with a specified pattern. This means precise classification cannot be expected when various types of failures including a block failure and a line failure exist, resulting in insufficient failure analysis.

In the method of failure analysis as disclosed in Japanese Patent Application Laid-Open No. 2000-306395, failure classification has no dependence on the number of failure bits. Therefore, failure analysis cannot use the detailed information indicative of the number of failure bits obtained from a fail bit map. Further, the failure analysis of Japanese Patent Application Laid-Open No. 2000-306395 only classifies a failure in a specified region as a line failure, a bit failure, or the like. Detailed failure analysis inside a block failure is not performed.

### SUMMARY OF THE INVENTION

It is an object of the present invention to provide a failure analysis method of a semiconductor device for performing detailed analysis of a block failure in a semiconductor device including classification of a block failure containing failure bits which have periodicity in a row direction or in a column direction (hereinafter alternatively referred to as “a block failure with periodicity”). Even when a semiconductor device contains both a bock failure with periodicity and a line failure, it is another object of the present invention to provide a failure analysis method of such a semiconductor device for performing failure analysis including classification into a block failure with periodicity and a line failure.

According to the present invention, the failure analysis method of a semiconductor device includes the following steps (a) through (g). In the step (a), in a fail bit map obtained from a semiconductor device including a plurality of memory cells arranged in a matrix, the number of failure bits is counted with respect to each row of a region classified as a block failure. In the step (b), the number of failure bits is counted with respect to each column of the region in the fail bit map. In the step (c), a first threshold value is found from an average value of the number of failure bits with respect to each row, to compare the number of failure bits with respect to each row and the first threshold value. In the step (d), a second threshold value is found from an average value of the number of failure bits with respect to each column, to compare the number of failure bits with respect to each column and the second threshold value. The step (e) is performed after the step (c). In the step (e), an average value of a result of comparison is found with respect to each row as an average value of rows. The step (f) is performed after the step (d). In the step (f), an average value of a result of comparison is found with respect to each column as an average value of columns. In the step (g), it is determined that the semiconductor device contains a block failure in a column direction, a block failure in a row direction, or a random block failure. The block failure in a column direction satisfies a condition that the average value of rows is greater than a value obtained by multiplying the average value of columns by a predetermined factor. The block failure in a row direction satisfies a condition that the average value of columns is greater than a value obtained by multiplying the average value of rows by the predetermined factor. The random block failure satisfies conditions that the average value of rows is not more than a value obtained by multiplying the average value of columns by the predetermined factor, and the average value of columns is not more than a value obtained by multiplying the average value of rows by the predetermined factor.

Information on a failure, which cannot be classified in the conventional method of failure analysis, can be given in further detail. As a result, failure analysis is allowed to provide an improved degree of precision in failure classification.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram illustrating a failure analysis method of a semiconductor device according to a first preferred embodiment of the present invention;

FIG. 2 is a fail bit map of a semiconductor device according to the first preferred embodiment of the present invention;

FIG. 3 is a fail bit map showing a block failure portion of the semiconductor device according to the first preferred embodiment of the present invention;

FIG. 4A is a fail bit map showing a block failure portion of a semiconductor device according to a second preferred embodiment of the present invention;

FIG. 4B shows the number of failure bits in each column according to the second preferred embodiment of the present invention;

FIG. 5A is a fail bit map showing a block failure portion of a semiconductor device according to a third preferred embodiment of the present invention;

FIG. 5B shows the number of failure bits in each column according to the third preferred embodiment of the present invention;

FIG. 6 is a fail bit map showing a block failure portion of a semiconductor device according to a fourth preferred embodiment of the present invention;

FIG. 7 is a flow chart explaining a failure analysis method of a semiconductor device according to a fifth preferred embodiment of the present invention;

FIGS. 8 and 9 are fail bit maps each showing a block failure portion of a semiconductor device according to a sixth preferred embodiment of the present invention;

FIG. 10 is a fail bit map showing a block failure portion of a semiconductor device according to a modification of the sixth preferred embodiment of the present invention;

FIG. 11 is a flow chart explaining a failure analysis method of a semiconductor device according to a seventh preferred embodiment of the present invention; and

FIG. 12 through 14 are fail bit maps each showing a block failure portion of a semiconductor device according to an eighth preferred embodiment of the present invention.

### DESCRIPTION OF THE PREFERRED EMBODIMENTS

First Preferred Embodiment

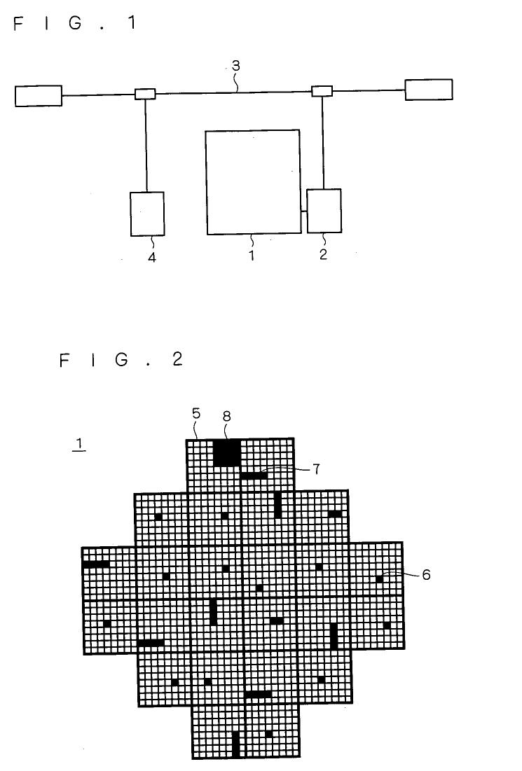

FIG. 1 is a block diagram illustrating a system for performing a failure analysis method of a semiconductor device according to a first preferred embodiment of the present invention. With reference to FIG. 1, a semiconductor device 1 is connected to an LSI tester 2 for measuring memory cells of the semiconductor device 1 by electrical characteristic. After measurement, the LSI tester 2 obtains data of the semiconductor device 1, which data is then transmitted to a data analysis EWS (engineering work station) 4 through a data circuit 3 such as a LAN. The data analysis EWS 4 analyzes the data of the semiconductor device 1 transmitted from the LSI tester 2, to classify a failure and specify the cause of the failure. In FIG. 1, blocks with no designation by reference numeral represent communication devices for constructing a network.

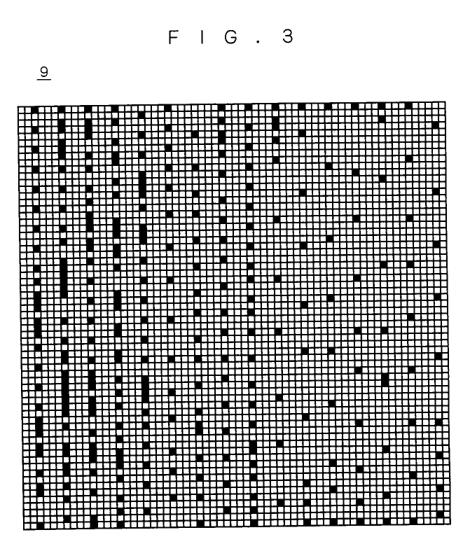

FIG. 2 is a fail bit map of the semiconductor device 1 according to the first preferred embodiment. With reference to FIG. 2, the semiconductor device 1 comprises 24 semiconductor chips 5 arranged on a semiconductor wafer. The semiconductor chips 5 each include 128×128 memory cells. Due to limitations of space, one square of each one of the semiconductor chips 5 represents 16×16 bits in FIG. 2, while an actual fail bit map holds data per bit. With reference to the fail bit map of FIG. 2, blank squares show normal memory cells (normal bits), whereas black squares show failure memory cells (failure bits). As stated, one square represents 16×16=256 bits. A square, with the number of failure bits of no smaller than a predetermined value, is filled in with black. As an example, the square including four failure bits or more out of 256 bits is filled in with black.

The fail bit map of FIG. 2 undergoes conventional failure classification. First, a pattern of a failure including failure bits displayed on the fail bit map is recognized. On the basis the coincidence rate of this pattern with a specified pattern previously defined or positional relation thereof with a peripheral failure, the failure is classified as a bit failure 6, a line failure 7, or a block failure 8. The bit failure 6 includes a single failure square. The line failure 7 includes a plurality of failure squares in a line. The block failure 8 includes a plurality of failure squares concentrated in a certain region.

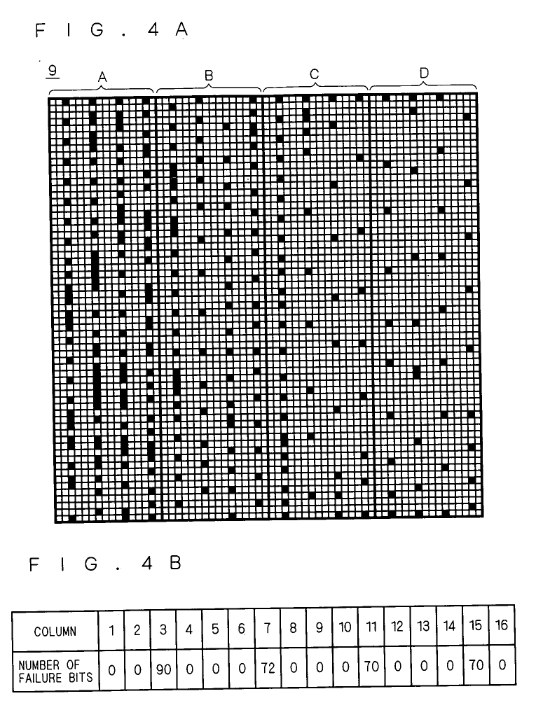

In the first preferred embodiment, failure analysis is targeted specifically for the block failure 8. FIG. 3 is a fail bit map showing the block failure 8 of the first preferred embodiment. In FIG. 2, the block failure 8 is shown to contain 4×4 squares each including 16×16 bits. A fail bit map 9 shown in FIG. 3 thus represents 64×64 bits. Similar to FIG. 2, blank squares show normal bits, whereas black squares show failure bits.

The failure analysis method of the first preferred embodiment will be described. First, the number of failure bits is counted with respect to each column and each row. With reference to FIG. 3, 13 failure bits exist in the first row, 7 in the tenth row, 2 in the twentieth row, 7 in the thirtieth row, and 10 in the sixty-fourth row. Further, the first column includes zero failure bit, and 36 failure bits exist in the seventh column, 20 in the thirty-first column, 10 in the fifty-fifth column, and 0 in the sixty-fourth column. After the numbers of failure bits are counted for all the rows and columns, the respective average numbers of failure bits are found with respect to rows and columns. One-half of the average number of failure bits of rows is defined as a threshold value of rows, and one-half of the average number of failure bits of columns is defined as a threshold value of columns. In the exemplary fail bit map of FIG. 3, the threshold value of rows is 2.36, and that of columns is 2.36. In the first preferred embodiment, the respective threshold values of rows and columns are obtained by multiplying the average numbers of failure bits of rows and columns by one-half, respectively. However, this multiplication factor is not limited to this in the present invention. An alternative value may be applicable as a factor in multiplication of the respective average numbers of failure bits of rows and columns, as long as such a value is suitable for a failure analysis method.

Thereafter, on the basis of the respective threshold values of rows and columns, the number of failure bits is converted to digital form with respect to each row and each column. More specifically, with respect to each row and column, the number of failure bits of not less than the corresponding threshold value is converted to 1, and the number of failure bits of less than the corresponding threshold value is converted to 0. With reference to the exemplary fail bit map of FIG. 3, the number of failure bits is converted to 1 in the first row, to 1 in the tenth row, to 0 in the twentieth row, to 1 in the thirtieth row, and to 1 in the sixty-fourth row. Further, the number of failure bit is converted to 0 in the first column, to 1 in the seventh column, to 1 in the thirty-first column, to 1 in the fifty-fifth column, and to 0 in the sixty-fourth column. Thereafter, respective average values of the digitized numbers of failure bits with respect to rows and columns are calculated, which are respectively referred to as average values of rows and columns. In the exemplary fail bit map of FIG. 3, the average value of rows is 0.84, whereas the average value of columns is 0.25.

Next, using the average values of rows and columns thereby calculated, classification of a block failure proceeds further. More particularly, when the average value of columns is greater than the value obtained by multiplying the average value of rows by a factor, it is determined that the semiconductor device 1 contains a block failure in a row direction. When the average value of rows is greater than a value obtained by multiplying the average value of columns by the factor, it is determined that the semiconductor device 1 contains a block failure in a column direction. When the average value of columns is not more than a value obtained by multiplying the average value of rows by the factor, and when the average value of rows is not more than a value obtained by multiplying the average value of columns by the factor, it is determined that the semiconductor device 1 contains a random block failure. As discussed, in the exemplary fail bit map of FIG. 3, the average value of rows is 0.84, whereas the average value of columns is 0.25. Setting a multiplication factor to be 1.2, the average value of rows is greater than a value obtained by multiplying the average value of columns by the factor as seen from the following expression:

0.84>0.25×1.2

In this case, it is determined that the semiconductor device 1 contains a block failure in a column direction.

In the first preferred embodiment, the respective threshold values of rows and columns are obtained by multiplying the respective average numbers of failure bits of rows and columns by one-half, which multiplication factor is not limited to this in the present invention. An alternative value, derived from previously obtained failure data, for example, can suitably be used as a factor in multiplication of the respective average numbers of failure bits of rows and columns. Further, the factor for failure classification is set to be 1.2 in the first preferred embodiment, which factor is not limited to this in the present invention. An alternative value, derived from previously obtained failure data, for example, can suitably be used as a factor for failure classification.

As described, in the failure analysis method of a semiconductor device according to the first preferred embodiment, it is determined that a semiconductor device contains a block failure in a column direction, a block failure in a row direction, or a random block failure. The block failure in a column direction satisfies a condition that the average value of rows is greater than a value obtained by multiplying the average value of columns by a predetermined factor. The block failure in a row direction satisfies a condition that the average value of columns is greater than a value obtained by multiplying the average value of rows by the predetermined factor. The random block failure satisfies conditions that the average value of rows is not more than a value obtained by multiplying the average value of columns by the predetermined factor, and the average value of columns is not more than a value obtained by multiplying the average value of rows by the predetermined factor. This means information on the failure, which cannot be classified in the conventional method of failure analysis, can be given in further detail. As a result, failure analysis of the first preferred embodiment is allowed to provide an improved degree of precision in failure classification.

Second Preferred Embodiment

In the first preferred embodiment, a block failure is classified into three types, namely, a block failure in a column direction, a block failure in a row direction, and a random block failure. In a second preferred embodiment of the present invention, a block failure classified as a block failure in a column direction or in a row direction in the first preferred embodiment undergoes further analysis. A block failure classified as a random block failure is not subjected to a failure analysis method of the second preferred embodiment.

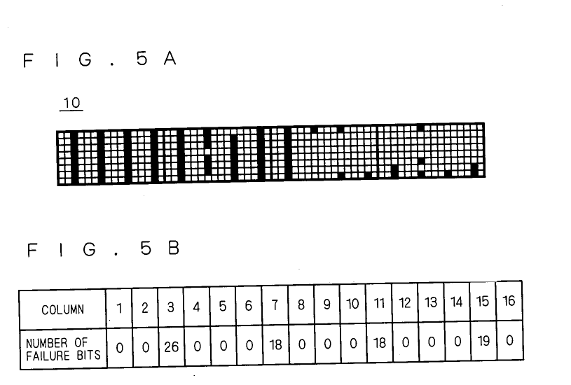

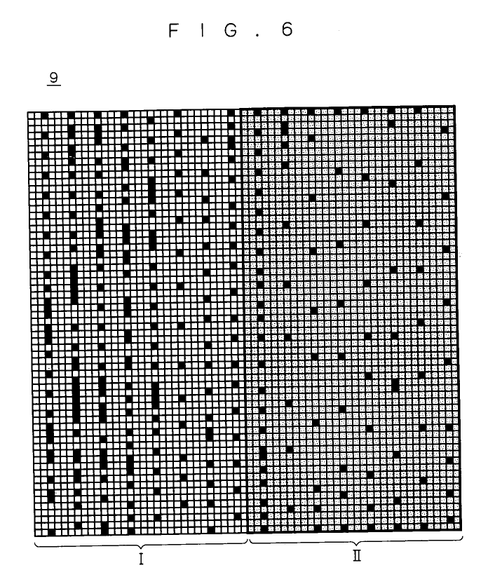

First, the fail bit map 9 classified as a block failure in a column direction, is divided in a column direction into equal sections with respect to the certain number of columns. The numbers of failure bits are counted which exist in the same-numbered columns in all of the sections. For example, the number of failure bits in the fifth column in one section, and the number of failure bits in the fifth column in another section, are respectively counted. As a result, the total number of failure bits is obtained with respect to each column. For example, the fail bit map 9 shown in FIG. 3 is divided into four sections each including 16 columns. The fail bit map 9 after division is as shown in FIG. 4A. With reference to the fail bit map 9 before division, a section A includes the first through sixteenth columns, a section B includes the seventeenth through thirty-second columns, a section C includes the thirty-third through forty-eighth columns, and a section D includes the forty-ninth through sixty-fourth columns. Next, the respective numbers of failure bits are counted which exist in the first column of the section A (the first column of the fail bit map 9 before division), in the first column of the section B (the seventeenth column of the fail bit map 9 before division), in the first column of the section C (the thirty-third section of the fail bit map 9 before division), and in the first column of the section D (the forty-ninth column of the fail bit map 9 before division). The counted numbers are then added together. With respect to the first column of each section, the total number is determined as zero. Following the same calculation with respect to the third column, the total number is determined as 90. The respective numbers of failure bits are counted which exist in the first through sixteenth columns. FIG. 4B shows the number of failure bits in each column of a group as an aggregate of the sections A through D.

Thereafter, the maximum value of the calculated number of failure bits is determined with respect to each column of the group. Defining one-half of this maximum value as a threshold value, the calculated number of failure bits in each column of the group and the threshold value are compared. After comparison, information of the column, with the number of failure bits which is not less than the threshold value, is taken out as data. With reference to FIG. 4B, the maximum value is 90 as the number of failure bits in the third column, which means a threshold value is 45. Comparison is made between the threshold value and the number of failure bits in each column. After comparison, the third, seventh, eleventh, and fifteenth columns, each having the number of failure bits greater than the threshold value, are taken out as data. That is, following the failure analysis method of the second preferred embodiment, the fail bit map 9 of FIG. 3 is classified as a block failure in a column direction containing failures in the third, seventh, eleventh, and fifteenth columns (hereinafter alternatively referred to as a block failure in a column direction (3, 7, 11, 15)).

A fail bit map, when classified as a block failure in a row direction, is divided in a row direction into sections each including the certain number of rows. Similar to the block failure in a column direction, the numbers of failure bits are counted which exist in the same-numbered rows in all of the sections. In the second preferred embodiment, the threshold value is obtained by multiplying the maximum value of the number of failure bits by one-half, which multiplication factor is not limited to this in the present invention. An alternative value, derived from previously obtained failure data, for example, can suitably be used as a factor in multiplication of the maximum value of the number of failure bits.

As described, the failure analysis method of a semiconductor device according to the second preferred embodiment comprises the following steps. In one step, a fail bit map classified as a block failure in a column or in a row direction, is divided in a column direction or in a row direction into equal sections with respect to the certain number of columns or to the number of rows, respectively. In another step, the respective numbers of failure bits existing in the same-numbered columns or rows are counted, to calculate the number of failure bits in each column or each row of a group as an aggregate of the sections of columns or rows. In still another step, a threshold value is found from the maximum value of the number of failure bits in each column or each row in the group of columns or rows, the threshold value and the number of failure bits in each column or each row in the group of columns or rows are compared, to extract a column or a row having the number of failure bits greater than the threshold value. This means information on the failure, which cannot be classified in the conventional method of failure analysis, can be given in further detail. As a result, failure analysis of the second preferred embodiment is allowed to provide an improved degree of precision in failure classification.

Third Preferred Embodiment

When the failure analysis method of the second preferred embodiment follows classification of a block failure of the first preferred embodiment, a failure analysis method of a third preferred embodiment of the present invention is employed prior to the failure analysis method of the second preferred embodiment. Similar to the second preferred embodiment, a block failure classified as a block failure in a column direction or in a row direction in the first preferred embodiment is thus targeted for failure analysis of the third preferred embodiment. A block failure classified as a random block failure is not subjected to the failure analysis method of the third preferred embodiment.

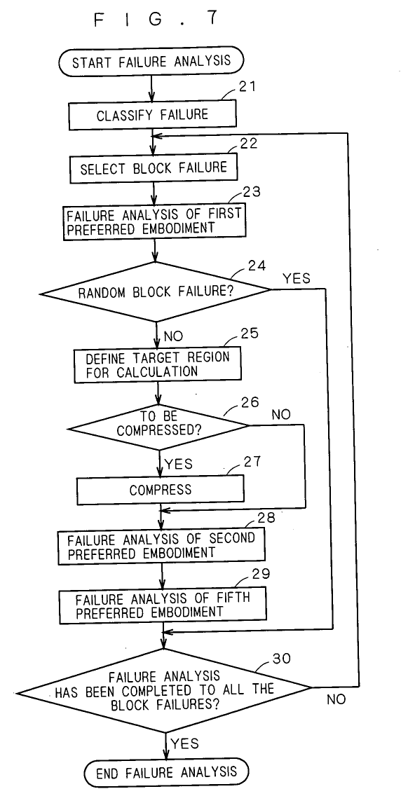

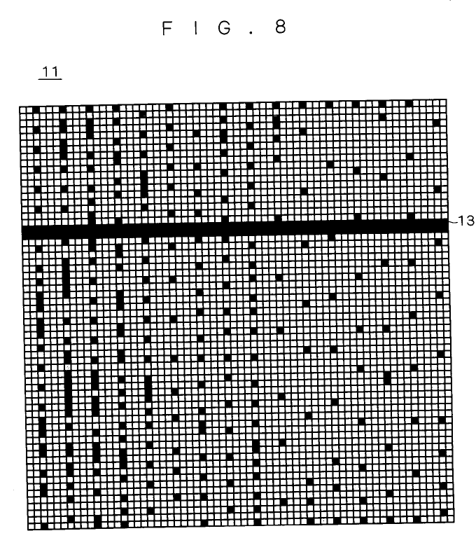

The third preferred embodiment first refers to a block failure classified as a block failure in a column direction. As a first step, a fail bit map is divided in a row direction into equal sections with respect to the certain number of rows. Next, a plurality of rows of each section is compressed into one row. That is, in each section, a plurality of bits defining one column is compressed into one bit. By way of example, the third preferred embodiment is applied to the fail bit map 9 of FIG. 3, the detail of which will be described. First, the fail bit map 9 of FIG. 3 is divided in a row direction into eight equal sections each including eight rows. In each section, eight bits defining one column is compressed into one bit. In compressing eight bits into one bit, when two or more failure bits exist in these eight bits, the bit after compression is represented as a failure bit. The result of such compression is as shown in FIG. 5A. In FIG. 5A, a fail bit map 10 after compression is shown which has 8 rows×64 columns.

The failure analysis method of the second preferred embodiment is applied to the fail bit map after compression. FIG. 5B shows the number of failure bits in each column of a group as an aggregate of the sections. The maximum value is determined from FIG. 5B. Defining one-half of this maximum value as a threshold value, the number of failure bits in each column and the threshold value are compared. After comparison, information of the column, having the number of failure bits of not less than the threshold value, is taken out as data. With reference to FIG. 5B, the maximum value is 26 as the number of failure bits in the third column, which means a threshold value is 13. Comparison is made between the threshold value and the number of failure bits in each column. After comparison, the third, seventh, eleventh, and fifteenth columns, each having the number of failure bits greater than the threshold value, are taken out as data. That is, according to the failure analysis method of the third preferred embodiment performed prior to the second preferred embodiment, the fail bit map 9 of FIG. 3 is also classified as a block failure in a column direction (3, 7, 11, 15).

In the third preferred embodiment, a fail bit map is degenerated by being divided in a row direction into equal sections with respect to the certain number of rows. A fail bit map may alternatively be compressed by being divided in a column direction into equal sections with respect to the certain number of columns. With regard to a block failure classified as a block failure in a row direction, a fail bit map is also divided in a row direction or in a column direction into equal sections with respect to the certain number of rows or to the certain number of columns, and in each section, bits representing one column or one row, respectively, are also compressed into one bit. In the third preferred embodiment, when two or more failure bits exist in eight bits targeted for compression, the bit after compression is represented as a failure bit. However, such a criterion is not limited to this. An alternative criterion, derived from previously obtained failure data, for example, can suitably be used to determine whether the bit after degeneracy is a failure or not. In the third preferred embodiment, further, the threshold value is obtained by multiplying the maximum value of the number of failure bits by one-half, which multiplication factor is not limited to this in the present invention. An alternative value, derived from previously failure data, for example, can suitably be used as a factor in multiplication of the maximum value of the number of failure bits.

As described, the failure analysis method of a semiconductor device according to the third preferred embodiment comprises the following steps. In one step, a fail bit map is divided in a row direction or in a column direction into equal sections with respect to the certain number of rows or to the certain numbers of columns, respectively. In another step, each column or each row in each section is converted to one failure bit when each column or each row contains the predetermined number of failure bits or more, and each column or each row in each section is converted to one normal bit when each column or each row contains the number of failure bits of less than the predetermined number, to form a fail bit map in which rows or columns defining the section is compressed into one row or one column, respectively. As a result, unnecessary noises can be eliminated from the result of conventional failure classification, leading to an improved degree of precision in failure classification.

Fourth Preferred Embodiment

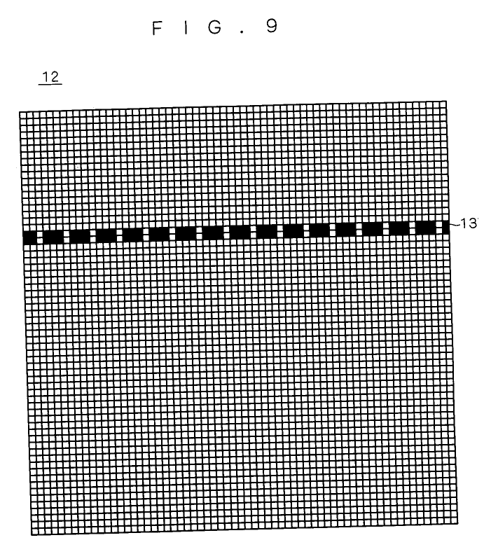

The failure analysis method of the second or third preferred embodiment is applied to the fail bit map 9 in its entirety showing a block failure as classified in the first preferred embodiment. According to a fourth preferred embodiment of the present invention, in the fail bit map 9 classified as a block failure in the first preferred embodiment, a region is previously defined as a target for the failure analysis method of the second or third preferred embodiment. FIG. 6 is the fail bit map 9 of the fourth preferred embodiment. With respect to the fail bit map 9 of FIG. 3, the left-half region having 32 columns×64 rows is defined as a target region I for calculation, and the right-half region having 32 columns×64 rows is defined as a region II exempt from calculation.

The failure analysis method of the second or third preferred embodiment is applied only to the region I previously defined as a target for calculation. The extent of the region I is not limited to the one shown in FIG. 6. The region I may extend in an alternative way on the basis of previously obtained failure data, for example,

As described, the failure analysis method of a semiconductor device according to the fourth preferred embodiment further comprises the step of previously defining an extent of the fail bit map 9 as a target for the failure analysis method. As a result, a target region for the failure analysis method is limited to a smaller extent, resulting in a considerable reduction in processing time.

Fifth Preferred Embodiment

In a fifth preferred embodiment of the present invention, periodicity is calculated on the basis of the information obtained in the second or third preferred embodiment indicative of rows or columns containing failure bits. With reference to the fail bit map 9 of FIG. 3, it is determined in the second or third preferred embodiment that the fail bit map 9 shows a block failure in a column direction (3, 7, 11, 15), from which it is seen that the fail bit map 9 exhibits four-column periodicity in frequency of occurrence of failure bits. According to the failure analysis method of the fifth preferred embodiment, it is thus allowed to classify the block failure shown in the fail bit map 9 of FIG. 3 as a block failure in a column direction containing failures in the third, seventh, eleventh, and fifteenth columns with four-column periodicity (hereinafter alternatively referred to as a block failure in a column direction (3, 7, 11, 15 with four-column periodicity)). With regard to a block failure in a row direction, on the basis of the information obtained in the second or third preferred embodiment indicative of rows containing failure bits, periodicity in frequency of occurrence of failure bits is calculated in a row direction.

As described, the failure analysis method of a semiconductor device according to the fifth preferred embodiment further comprises the step of calculating periodicity in frequency of occurrence of failure bits in a column direction or in a row direction, with respect to a fail bit map showing a failure classified as a block failure in a column direction or in a row direction. As a result, failure classification and analysis are performed on a block failure having periodicity with a high degree of precision.

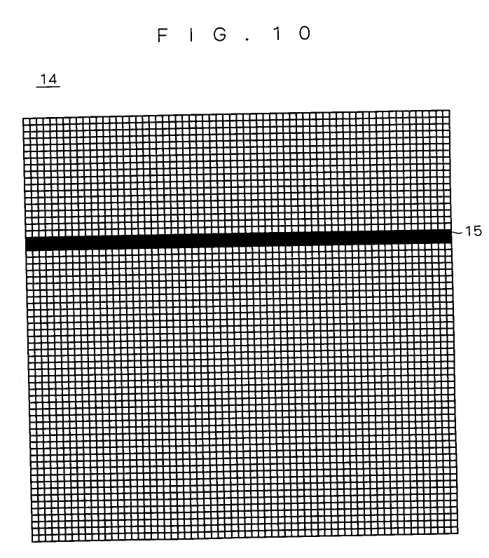

FIG. 7 is a flow chart explaining the failure analysis method according to the first through fifth preferred embodiments. When failure analysis starts, the semiconductor device 1 is subjected to failure classification into the bit failure 6, the line failure 7, and the block failure 8 (step 21). Next, the block failure 8 is selected from the result of classification in step 21 (step 22). Thereafter, the selected block failure 8 is subjected to failure analysis of the first preferred embodiment to be classified as a block failure in a column direction, a block failure in a row direction, or a random block failure (step 23).

Based on the result of step 23, it is determined whether the block failure 8 is a random block failure or not (step 24). When the block failure 8 is not determined to as a random block failure in step 24, the target region I for calculation is defined in the fail bit map 9 which extends a predetermined range (step 25).

Thereafter, it is determined whether the fail bit map 9 including the target region I for calculation defined in step 25 is to be compressed (step 26). If the fail bit map 9 is to be compressed, the failure analysis method of the third preferred embodiment is employed to compress the fail bit map 9 (step 27). Thereafter, the compressed fail bit map 9 is subjected to the failure analysis method of the second preferred embodiment (step 28). If the fail bit map 9 is not to be compressed, the failure analysis method of the second preferred embodiment is also employed.

Next, the result obtained in step 28 is subjected to the failure analysis method of the fifth preferred embodiment (step 29). Subsequently, it is judged whether the failure analysis has been completed to all the block failures 8 in the semiconductor device 1 (step 30). If the failure analysis has been completed to all the block failures 8 in the semiconductor device 1, the failure analysis ends. If the failure analysis has not been completed to all the block failures 8, another one of the block failures 8 classified in step 23 is selected. This block failure 8 is then determined to as a random block failure or not (step 24). When the block failure 8 is determined to as a random block failure, the block failure 8 presently selected does not undergo failure analysis. The failure analysis goes to step 30.

Sixth Preferred Embodiment

According to a failure analysis method of a sixth preferred embodiment of the present invention, in a block failure containing both failure bits having periodicity in frequency of occurrence in a column direction or in a row direction and other failure bits, these other failure bits are specified. First, a block failure undergoes failure analysis of the fifth preferred embodiment, to obtain information indicative of rows or columns containing failure bits such as periodicity. On the basis of the information thereby obtained, failure bits having periodicity are removed. As a result, failure bits other than those with periodicity are specified in a fail bit map.

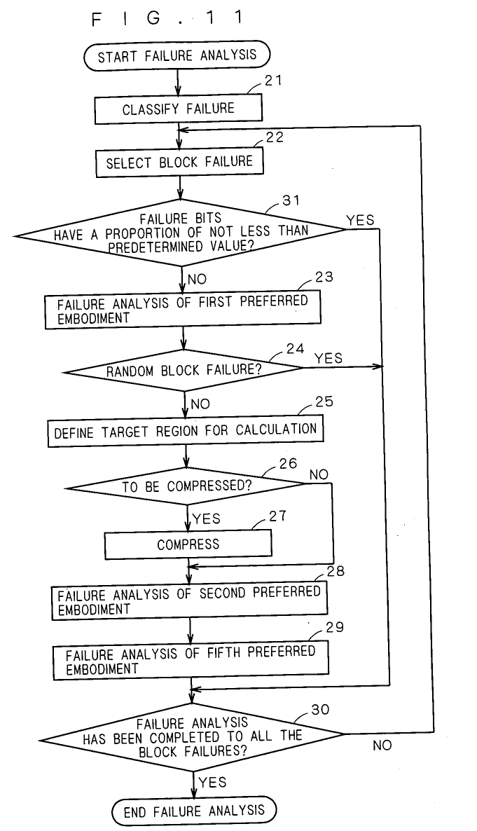

A line failure 13 in a row direction is superimposed on the nineteenth and twentieth rows of the fail bit map 9 of FIG. 3, which result is shown in FIG. 8 as a fail bit map 11. The failure analysis method of the fifth preferred embodiment is performed on the fail bit map 11, whereby it is determined that the fail bit map 11 shows a block failure in a column direction (3, 7, 11, 15 with four-column periodicity). On the basis of this result, failure bits are removed from the fail bit map 111 which exist in the third, and the subsequent columns equally spaced therefrom with four-column periodicity, which result is shown in FIG. 9 as a fail bit map 12. In FIG. 9, the line failure 13 is shown in the nineteenth and twentieth rows. The line failure 13 is represented by dashed lines indicating removed failure bits in the third, and the subsequent columns equally spaced therefrom with four-column periodicity. Following the conventional failure classification for making comparison with a specified pattern, the line failure 13 in a row direction is recognized in the nineteenth and twentieth rows in the fail bit map 12.

As described, the failure analysis method of a semiconductor device according to the sixth preferred embodiment further comprises the step of removing failure bits having periodicity in frequency of occurrence in a column direction or in a row direction from a fail bit map. When a fail bit map contains both failure bits having such periodicity and other failure bits superimposed on the failure bits with periodicity, these other failure bits can be subjected to classification and analysis with a high degree of precision.

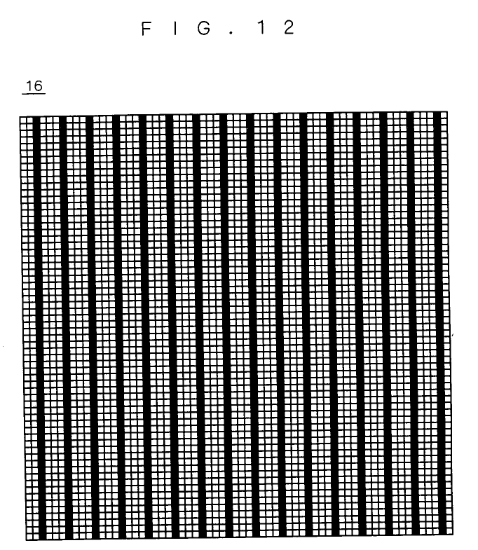

According to a modification of the sixth preferred embodiment, the fail bit map 12 of FIG. 9 is complemented to form a fail bit map 14 shown in FIG. 10. In the fail bit map 12, the line failure 13 is represented by dashed lines as a result of removal of failure bits having periodicity. Such a line failure may not be regarded as the line failure 13 as shown in FIG. 8 in recognition of a failure pattern. In response, the line failure 13 in the fail bit map 12 represented by dashed lines is complemented using remaining failure bits, to define a line failure 15 represented by solid lines.

As an exemplary way of complement, relative to a memory cell in the line failure 13 from which a failure bit is removed after removal of failure bits with periodicity, five bits on the right and left are counted. If these ten bits include five failure bits or more, this memory cell is recognized as a failure bit. If these ten bits include failure bits of less than five, conversely, this memory cell is recognized as a normal bit. The way of complement is not limited to this, as long as it uses remaining failure bits.

As described, the failure analysis method of a semiconductor device according to the sixth preferred embodiment further comprises the step of performing data complement on a fail bit map from which failure bits having periodicity have been removed, on the basis of remaining failure bits. When a fail bit map contains both failure bits having periodicity and other failure bits superimposed thereon, these other failure bits can be subjected to classification and analysis with a higher degree of precision.

Seventh Preferred Embodiment

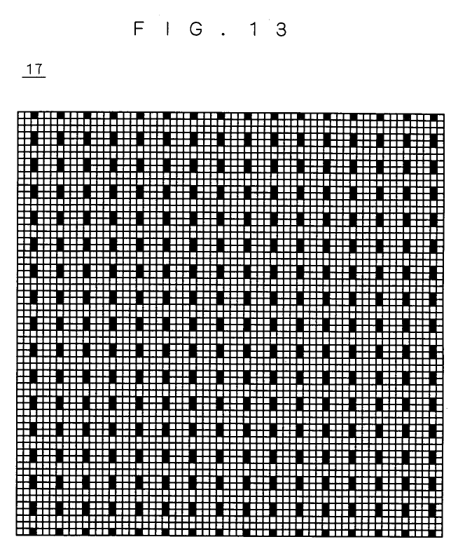

In a seventh preferred embodiment of the present invention, on the basis of a proportion of failure bits in a block failure, it is determined whether a block failure is to be subjected to the failure analysis method according to the first and the subsequent preferred embodiments. FIG. 11 is a flow chart explaining the failure analysis method according to the seventh preferred embodiment.

When failure analysis starts, the semiconductor device 1 is subjected to failure classification into the bit failure 6, the line failure 7, and the block failure 8 (step 21). Next, the block failure 8 is selected from the result of classification in step 21 (step 22). Thereafter, a proportion of failure bits is calculated in the block failure 8, and is determined whether it has a value of not less than a predetermined value (step 31). If such a proportion has a predetermined value or more, the failure analysis proceeds to step 30 to judge whether the failure analysis has been completed to all the block failures 8 in the semiconductor device 1. If a proportion of failure bits in the block failure 8 is determined to be smaller than the predetermined value in step 31, the selected block failure 8 is subjected to failure classification of the first preferred embodiment to be classified as a block failure in a column direction, a block failure in a row direction, or a random block failure (step 23).

Based on the result of step 23, it is determined whether the block failure 8 is a random block failure or not (step 24). When the block failure 8 is not determined as a random block failure in step 24, the target region I for calculation is defined in the fail bit map 9 which extends a predetermined range (step 25).

Thereafter, it is determined whether the fail bit map 9 including the target region I for calculation defined in step 25 is to be compressed (step 26). If the fail bit map 9 is to be compressed, the failure analysis method of the third preferred embodiment is employed to compress the fail bit map 9 (step 27). Thereafter, the compressed fail bit map 9 is subjected to the failure analysis method of the second preferred embodiment (step 28). If the fail bit map 9 is not to be compressed, the failure analysis method of the second preferred embodiment is also employed.

Next, the result obtained in step 28 is subjected to the failure analysis method of the fifth preferred embodiment (step 29). Subsequently, it is judged whether the failure analysis has been completed to all the block failures 8 in the semiconductor device 1 (step 30). If the failure analysis has been completed to all the block failures 8 in the semiconductor device 1, the failure analysis ends. If the failure analysis has not been completed to all the block failures 8, another one of the block failures 8 classified in step 23 is selected. This block failure 8 is then determined as a random block failure or not (step 24). When the block failure 8 is determined as a random block failure, the block failure 8 presently selected does not undergo failure analysis. The failure analysis goes to step 30.

As described, the failure analysis method of a semiconductor device according to the seventh preferred embodiment further comprises the step of calculating a proportion of failure bits contained in a fail bit map. When failure bits have a proportion of not less than a predetermined value, the failure analysis omits the failure analysis method according to the first through fifth preferred embodiments. That is, only the required block failure can be subjected to the failure analysis, resulting in a consideration reduction in processing time in failure analysis of a semiconductor device.

Eighth Preferred Embodiment

According to an eighth preferred embodiment of the present invention, the block failure 8 as classified by the failure analysis method of the second or third preferred embodiment undergoes classification in further detail. In the second or third preferred embodiment, the fail bit map 9 of FIG. 3 is classified as a block failure in a column direction (3, 7, 11, 15). In the eighth preferred embodiment, information indicative of a proportion of failure bits or a distribution of failure bits is also used to perform classification of the block failure 8 in further detail.

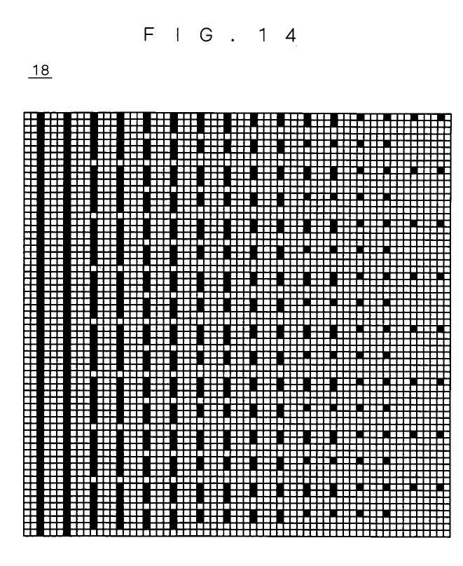

With reference to fail bit maps 16, 17 and 18 shown in FIGS. 12, 13 and 14, respectively, the eighth preferred embodiment will be described more specifically. According to the failure analysis method of the second or third preferred embodiment, the fail bit maps 16, 17 and 18 of FIGS. 12, 13 and 14 are each simply classified as a block failure in a column direction (3, 7, 11, 15). As seen from FIGS. 12, 13 and 14, however, the fail bit maps 16, 17 and 18 show different types of block failures. The fail bit map 16 of FIG. 12 contain line failures in a column direction represented by solid lines, whereas in the fail bit map 17 of FIG. 13, line failures in a column direction represented by dashed lines each have a proportion of failure bits of 50% relative to the line failure represented by solid lines. In the fail bit map 18 of FIG. 14, two line failures from the left are represented by solid lines, and lines failures are represented by shorter dashed lines as they go farther towards the right from these two line failures.

In the eighth preferred embodiment, information indicative of a proportion of failure bits or a distribution of failure bits is also used to perform classification of the block failure 8 in further detail. As an exemplary way to examine distribution of failure bits, it is judged whether the block failure 8 has a coincidence rate of a certain value or more with a previously specified pattern of a fail bit map. Such examination of distribution of failure bits may be performed by an alternative way.

With respect to the fail bit map 16 of FIG. 12, information indicative of line failures represented by solid lines is added to a block failure in a column direction (3, 7, 11, 15), whereby the fail bit map 16 is classified as a block failure in a column direction (solid lines: 3, 7, 11, 15). With respect to the fail bit map 17 of FIG. 13, information indicative of line failures represented by dashed lines each having a proportion of failure bits of 50% is added to a block failure in a column direction (3, 7, 11, 15), whereby the fail bit map 17 is classified as a block failure in a column direction (dashed lines (50%): 3, 7, 11, 15). With respect to the fail bit map 18 of FIG. 14, information indicative of line failures exhibiting gradual change in proportion of failure bits is added to a block failure in a column direction (3, 7, 11, 15), whereby the fail bit map 18 is classified as a block failure in a column direction (dashed lines (gradation): 3, 7, 11, 15).

As described, the failure analysis method of a semiconductor device according to the eighth preferred embodiment further comprises the step of classifying a block failure having periodicity on the basis of information indicative of a proportion of failure bits and a distribution of failure bits in the block failure. As a result, the block failure can be classified in more detail, leading to a high degree of precision in failure analysis.

While the invention has been shown and described in detail, the foregoing description is in all aspects illustrative and not restrictive. It is therefore understood that numerous modifications and variations can be devised without departing from the scope of the invention.

What is claimed is:

1. A failure analysis method of a semiconductor device, comprising the steps of:
(a) in a fail bit map obtained from a semiconductor device including a plurality of memory cells arranged in a matrix, counting the number of failure bits with respect to each row of a region classified as a block failure;
(b) in said fail bit map, counting the number of failure bits with respect to each column of said region;
(c) finding a first threshold value from an average value of said number of failure bits with respect to each row, to compare said number of failure bits with respect to each row and said first threshold value;
(d) finding a second threshold value from an average value of said number of failure bits with respect to each column, to compare said number of failure bits with respect to each column and said second threshold value;
(e) after said step (c), calculating an average value of a result of comparison with respect to each row as an average value of rows;
(f) after said step (d), calculating an average value of a result of comparison with respect to each column as an average value of columns;
(g) determining that said semiconductor device contains a block failure in a column direction, a block failure in a row direction, or a random block failure, said block failure in a column direction satisfying a condition that said average value of rows is greater than a value obtained by multiplying said average value of columns by a predetermined factor, said block failure in a row direction satisfying a condition that said average value of columns is greater than a value obtained by multiplying said average value of rows by said predetermined factor, said random block failure satisfying conditions that said average value of rows is not more than a value obtained by multiplying said average value of columns by said predetermined factor, and said average value of columns is not more than a value obtained by multiplying said average value of rows by said predetermined factor.

2. The failure analysis method according to claim 1, further comprising the steps of:
(h) dividing said fail bit map in a column direction, classified as said block failure in a column direction, into equal sections with respect to the certain number of columns;
(i) counting the respective numbers of failure bits existing in the same-numbered columns in all of said sections, to calculate the number of failure bits in each column of a group as an aggregate of said sections of columns; and
(j) finding a third threshold value from a maximum value of the number of failure bits in each column of said group, and comparing said third threshold value and the number of failure bits in each column, to extract a column having the number of failure bits greater than said third threshold value.

3. The failure analysis method according to claim 1, further comprising the steps of:
(k) dividing said fail bit map in a row direction, classified as said block failure in a row direction, into equal sections with respect to the certain number of rows;
(l) counting the respective numbers of failure bits existing in the same-numbered rows in all of said sections, to calculate the number of failure bits in each row of a group as an aggregate of said sections of rows; and
(m) finding a fourth threshold value from a maximum value of the number of failure bits in each row of said group, and comparing said fourth threshold value and the number of failure bits in each row, to extract a row having the number of failure bits greater than said fourth threshold value.

4. The failure analysis method according to claim 2, further comprising the steps of:
(n) after said step (g), dividing said fail bit map in a row direction into equal sections with respect to the certain number of rows, and
(o) in each section, converting each column to one failure bit when said column contains the predetermined number of failure bits or more, and converting each column to one normal bit when said column contains the number of failure bits of less than said predetermined number, to form a fail bit map in which rows defining said section is compressed into one row.

5. The failure analysis method according to claim 3, further comprising the steps of:
(p) after said step (g), dividing said fail bit map in a column direction into equal sections with respect to the certain number of columns, and
(q) in each section, converting each row to one failure bit when said row contains the predetermined number of failure bits or more, and converting each row to one normal bit when said row contains the number of failure bits of less than said predetermined number, to form a fail bit map in which columns defining said section is compressed into one column.

6. The failure analysis method according to claim 1, further comprising the step of:
(r) previously defining an extent of said failure bit map as a target for the failure analysis method.

7. The failure analysis method according to claim 2, further comprising the step of:
(s) on the basis of a result of extraction in said step (j), calculating periodicity in frequency of occurrence of failure bits in a column direction.

8. The failure analysis method according to claim 3, further comprising the step of:
(t) on the basis of a result of extraction in said step (m), calculating periodicity in frequency of occurrence of failure bits in a row direction.

9. The failure analysis method according to claim 7, further comprising the step of:
(u) removing failure bits having said periodicity in a column direction from said fail bit map.

10. The failure analysis method according to claim 8, further comprising the step of:
(v) removing failure bits having said periodicity in a row direction from said fail bit map.

11. The failure analysis method according to claim 9, further comprising the step of:
(w) on the basis of remaining failure bits, performing data complement on said fail bit map from which failure bits having said periodicity in a column direction have been removed.

12. The failure analysis method according to claim 10, further comprising the step of:
(x) on the basis of remaining failure bits, performing data complement on said fail bit map from which failure bits having said periodicity in a row direction have been removed.

13. The failure analysis method according to claim 1, further comprising the step of:
(y) prior to said step (a), calculating a proportion of failure bits contained in said fail bit map, wherein
when failure bits have said proportion of not less than a predetermined value, said steps (a) through (x) are omitted.

14. The failure analysis method according to claim 7, further comprising the step of:
(z) classifying said block failure having said periodicity in a column direction on the basis of information indicative of a proportion of failure bits and a distribution of failure bits in said block failure.

15. The failure analysis method according to claim 8, further comprising the step of:
(A) classifying said block failure having said periodicity in a row direction on the basis of information indicative of a proportion of failure bits and a distribution of failure bits in said block failure.
